(19) United States
(12) Patent Application Publication
(10) Pub. No.: US 2023/0142541 A1
(43) Pub. Date: May 11, 2023

(54) SUPERJUNCTION SEMICONDUCTOR DEVICE AND METHOD FOR MANUFACTURING SAME

(71) Applicant: DB HiTek Co., Ltd., Bucheon-si (KR)

(72) Inventors: Ji Eun LEE, Bucheon-si (KR); Kwang Young KO, Bucheon-si (KR); Jong Min KIM, Seoul (KR)

(21) Appl. No.: 18/049,053

(22) Filed: Oct. 24, 2022

(30) Foreign Application Priority Data
Nov. 8, 2021 (KR) 10-2021-0151941

(51) Int. Cl. H01L 29/78; H01L 29/08; H01L 29/66; H01L 29/788

(52) U.S. Cl. CPC H01L 29/7811; H01L 29/0865; H01L 29/66545; H01L 29/66825; H01L 29/7889; H01L 29/66712; H01L 29/1095

(57) ABSTRACT

Disclosed is a superjunction semiconductor device and a method for manufacturing the same and, more particularly, to a superjunction semiconductor device and a method for manufacturing the same seeking to improve a switching speed and thus to improve switching characteristics by reducing a gate-to-drain parasitic capacitance (Cgd) and/or configuring a gate electrode as a floating dummy gate.

### CROSS REFERENCE TO RELATED APPLICATION

The present application claims priority to Korean Patent Application No. 10-2021-0151941, filed Nov. 8, 2022, the entire contents of which are incorporated herein for all purposes by this reference.

### BACKGROUND OF THE INVENTION

### Field of the Invention

The present disclosure relates to a superjunction semiconductor device and a method for manufacturing the same and, more particularly, to a superjunction semiconductor device and a method for manufacturing the same seeking to improve a switching speed and thus to improve switching characteristics by reducing a gate-drain parasitic capacitance (Cgd) by configuring a gate electrode as a floating dummy gate.

### Description of the Related Art

Generally, high-voltage semiconductor devices such as a metal-oxide-semiconductor field-effect transistor (MOSFET) and an insulated-gate bipolar transistor (IGBT) have a source region and a drain region above and below a drift region, respectively. The high-voltage semiconductor devices also have a gate insulating film above the drift region adjacent to the source region, and a gate electrode on the gate insulating film. In the on-state of the high voltage semiconductor device, the drift region provides a conductive path for a drift current flowing from the drain region to the source region, while in the off-state, the drift region provides a depletion region that is vertically extended by an applied reverse bias voltage.

On the basis of characteristics of the depletion region provided by the drift region, a breakdown voltage of the high voltage semiconductor device is determined. Regarding high voltage semiconductor devices, in order to minimize conduction loss in the on-state and secure a fast switching speed, research that aims to reduce on-state resistance of the drift region is ongoing. It is generally known that the on-state resistance of the drift region may be reduced by increasing the impurity concentration in the drift region. Yet, when the impurity concentration in the drift region is increased, the breakdown voltage decreases due to a space charge expansion in the drift region.

To solve this, a high voltage semiconductor device having a superjunction structure, capable of obtaining a high breakdown voltage while reducing the on-state resistance, is being used.

FIG. 1 is a cross-sectional view illustrating a conventional typical superjunction semiconductor device.

Hereinafter, the structure of a conventional superjunction semiconductor device 9 and its problems will be briefly described with reference to the accompanying drawings.

Referring to FIG. 1, in the typical superjunction semiconductor device 9, pillar regions 920 having a first conductive type are spaced apart from each other in an epitaxial layer 910 having a second conductive type. A body region 930 having the first conductivity type is formed on or over an individual pillar region 920, and source regions 940 having the second conductivity type are formed in the body region 930. In addition, a gate 950 is formed on or over the epitaxial layer 910, and a gate oxide film 960 is between the gate 950 and the epitaxial layer 910. The source regions 940 form current paths through the epitaxial layer 910 on both sides of the pillar region 920.

In general high-voltage and high-current power systems, when a short-circuit fault occurs, high voltage and high current are simultaneously applied to a device, resulting in high power consumption. If this phenomenon continues, the junction temperature rises, which may eventually destroy the device. When two source regions 940, one each on the left and right sides in the body region 930, are formed, a current value (Isc) in the short-circuit fault state may be relatively large. To prevent this, a method in which only one source region 940 is formed on one side of the body region 930 has been proposed, in order to reduce the area of the source region 940.

As such, when forming one source region 940 in the individual body region 930 in order to relatively lower the short-circuit current value (Isc) in the conventional superjunction semiconductor device 9, the side of the body region 930 without a source region 940 does not function as a channel, but the gate 950 is still formed thereover, and thus a gate-drain parasitic capacitance (Cgd) is maintained. The gate-drain parasitic capacitance (Cgd) has a linear relationship with the area between the epitaxial layer 910 and the gate oxide film 960. Moreover, since neither a channel nor a current path is formed, the resistance becomes relatively large, which causes a decrease in the switching speed of the semiconductor device 9 and deterioration of the corresponding switching characteristics.

### Document of Related Art

Korean Patent Application Publication No. 10-2005-0052597, entitled “SUPERJUNCTION SEMICONDUCTOR DEVICE.”

### SUMMARY OF THE INVENTION

To solve the above-mentioned problems, the present disclosure discloses a novel superjunction semiconductor device having an improved structure that lowers the gate-drain parasitic capacitance (Cgd), and a method for manufacturing the same.

The present disclosure has been made to solve the problems of the related art, and an objective of the present disclosure is to provide a superjunction semiconductor device and a method for manufacturing the same, seeking to improve a switching speed and thus to improve switching characteristics by reducing a gate-drain parasitic capacitance (Cgd) and configuring a gate electrode as a floating dummy gate. The floating dummy gate may be adjacent to a side or edge of a body region that does not contain a source, or it may be on or over a side or edge of the body region opposite from the side of the body region that does contain a source.

Moreover, an objective of the present disclosure is to provide a superjunction semiconductor device and a method for manufacturing the same, seeking to improve step coverage (e.g., in the method of manufacturing the superjunction semiconductor device) by forming a dummy gate as described herein, to maintain approximately equal spacing between adjacent gate electrodes and/or dummy gates, and/or to keep the spacing between gate electrodes and adjacent dummy gates sufficiently small to reduce or eliminate dishing and other uneven surfaces in layers of material deposited on or over the gate electrodes and dummy gates.

Furthermore, an objective of the present disclosure is to provide a superjunction semiconductor device and a method for manufacturing the same, which enable easy control of channel density by controlling the separation distance between gate electrodes and/or by arranging electrodes to cross a pillar region.

According to one or more embodiments of the present disclosure, there is provided a superjunction semiconductor device, including a substrate; a drain electrode on a substrate; an epitaxial layer on the substrate; a plurality of pillar regions spaced apart from each other in the epitaxial layer (e.g., alternating with portions of the epitaxial layer at a predetermined height or depth); a gate electrode on the epitaxial layer; a dummy gate on the epitaxial layer; a body region in the epitaxial layer; and a source region in the body region, wherein the source region may be under or adjacent to the gate electrode or a sidewall thereof, but not under or adjacent to the dummy gate or a sidewall thereof.

According to another embodiment of the present disclosure, in the superjunction semiconductor device, the dummy gate may extend in a same direction as the gate electrode, and may be (or have at least one side) between a pair of adjacent gate electrodes.

According to still another embodiment of the present disclosure, the superjunction semiconductor device may comprise a plurality of gate electrodes and a plurality of dummy gates, the dummy gates may extend in a same direction as the gate electrodes, and the dummy gates alternate with the gate electrodes.

According to still another embodiment of the present disclosure, in the superjunction semiconductor device, the dummy gate may be physically separate from a gate node.

According to still another embodiment of the present disclosure, in the superjunction semiconductor device, the pillar regions may be spaced apart from each other in a first direction, and the gate electrode and the dummy gate may extend in the first direction, and may be spaced apart from an adjacent gate electrode and/or an adjacent dummy gate in a second direction. The second direction may be orthogonal to the first direction.

According to still another embodiment of the present disclosure, there is provided a superjunction semiconductor device, including a substrate; a drain electrode on the substrate; an epitaxial layer having a second conductivity type on the substrate; a plurality of pillar regions spaced apart from each other in a first direction in the epitaxial layer (e.g., alternating in the first direction with portions of the epitaxial layer along the first direction at a predetermined height or depth); a plurality of gate electrodes extending in a second direction on the epitaxial layer, spaced apart from adjacent ones of the gate electrodes in the first direction; a plurality of dummy gates extending in the second direction on the epitaxial layer, spaced apart from adjacent ones of the gate electrodes and/or adjacent ones of the dummy gates in the first direction; a body region having a first conductivity type in the epitaxial layer and on or over one or more of the pillar regions; and a source region having the second conductivity type in the body region. For example, the superjunction semiconductor device may comprise a plurality of body regions and a plurality of source regions, and there may be only one source region in each of the body regions (e.g., the body regions and the source regions may be in a 1:1 relationship).

According to still another embodiment of the present disclosure, in the superjunction semiconductor device, each of the gate electrodes may at least partially overlap a corresponding one of the source regions in a vertical direction, and each of the dummy gates may have a shorter length in the second direction than the gate electrodes.

According to still another embodiment of the present disclosure, in the superjunction semiconductor device, the dummy gates may not overlap any of the source regions in the vertical direction.

According to still another embodiment of the present disclosure, in the superjunction semiconductor device, the dummy gates may correspond one-to-one with the gate electrodes.

According to an embodiment of the present disclosure, there is provided a method for manufacturing a superjunction semiconductor device, the method including forming a plurality of epitaxial layers on a substrate; forming an implant layer including an impurity region having a first conductivity type on or in one or more of the epitaxial layers; forming a pillar region in the one or more epitaxial layers by diffusion; forming a gate electrode on or over the epitaxial layers; and forming a dummy gate on or over the epitaxial layers (e.g., so that the dummy gate is not connected to a gate node), wherein the gate electrode and the dummy gate may extend in a direction substantially orthogonal to the pillar region along a horizontal direction.

According to another embodiment of the present disclosure, the method for manufacturing a superjunction semiconductor device further includes forming a body region in the epitaxial layer(s) (e.g., connected to the pillar region) and overlapping the gate electrode and/or the dummy gate; and forming a source region in the body region so that the source region does not overlap the dummy gate.

According to still another embodiment of the present disclosure, in the method for manufacturing a superjunction semiconductor device, the source region may overlap a sidewall of the gate electrode in a vertical direction.

According to still another embodiment of the present disclosure, in the method for manufacturing a superjunction semiconductor device, the dummy gate may have a substantially same cross-sectional shape as the gate electrode.

According to still another embodiment of the present disclosure, a method for manufacturing a superjunction semiconductor device includes forming an epitaxial layer on a substrate; forming a plurality of pillar regions spaced apart from each other in a first direction in the epitaxial layer; forming, in the epitaxial layer, a body region having a first body portion and a second body portion on one of the pillar regions; forming a source region in the first body portion; forming a gate electrode on the epitaxial layer and adjacent to and/or over the first body portion; and forming a dummy gate on or over the epitaxial layer and adjacent to and/or over the second body portion.

According to still another embodiment of the present disclosure, in the method for manufacturing a superjunction semiconductor device, the dummy gate may be formed on or over the second body portion (e.g., on a side of the body region without the source region).

According to still another embodiment of the present disclosure, in the method for manufacturing a superjunction semiconductor device, the dummy gate may be floating.

According to still another embodiment of the present disclosure, in the method for manufacturing a superjunction semiconductor device, the source region may extend in a second direction together with the gate electrode, the dummy gate, and the pillar region.

The present disclosure may have one or more of the following effects by one or more of the above configurations.

The present disclosure can improve a switching speed and thus improve switching characteristics by reducing a gate-drain parasitic capacitance (Cgd) and/or configuring a gate electrode as a dummy floating gate. For example, the dummy floating gate may be on or over a side or edge of a body region not containing a source region, or not forming a channel region (e.g., opposite from the side of the body region containing the source region).

In addition, the present disclosure can improve step coverage by forming a dummy gate to maintain approximately equal spacing between adjacent gate electrodes and/or dummy gates, and/or to keep the spacing between gate electrodes and adjacent dummy gates sufficiently small, as described herein.

Moreover, the present disclosure can enable easy control of channel density by controlling the separation distance between gate electrodes and/or arranging electrodes to cross a pillar region.

Meanwhile, it should be added that even if certain effects are not explicitly mentioned herein, the effects described in the following specification that are expected by the technical features of the present disclosure and their potential effects are treated as if they were described in the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional typical superjunction semiconductor device;

FIG. 2 is a plan view of a superjunction semiconductor device according to a first embodiment of the present disclosure;

FIG. 3 is a cross-sectional view of the superjunction semiconductor device illustrated in FIG. 2 along the line A-A;

FIG. 4 is a cross-sectional view of the superjunction semiconductor device illustrated in FIG. 2 along the line B-B;

FIG. 5 is a plan view of a superjunction semiconductor device according to a second embodiment of the present disclosure;

FIG. 6 is a cross-sectional view of the superjunction semiconductor device illustrated in FIG. 5 along the line C-C;

FIGS. 7 to 11 are reference views illustrating structures made during a method of manufacturing the superjunction semiconductor device according to the first embodiment of the present disclosure; and

FIGS. 12 to 16 are reference views illustrating structures made during a method of manufacturing the superjunction semiconductor device according to the second embodiment of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those skilled in the art.

As used herein, the singular form may include the plural form unless the context clearly dictates otherwise. Furthermore, as used herein, “comprise” and/or “comprising” refer to the specific existence of the recited shapes, numbers, steps, actions, members, elements and/or groups thereof, and do not exclude the presence or addition of one or more other shapes, numbers, actions, members, elements and/or groups.

Hereinafter, it should be noted that when one component (or layer) is described as being on another component (or layer), one component may be directly on another component, or one or more other components or layers may be between the components. In addition, when one component is expressed as being directly on or above another component, no other component(s) are located between the one component and the other component. Moreover, being located on “top,” “upper,” “lower,” “above,” “below,” “bottom” or “one (first) side” or “a side” of a component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term “metal oxide semiconductor” or “MOS” used below is a general term, and “M” is not limited to only metal and may refer to any of various types of conductors. Also, “S” may refer to a substrate or a semiconductor structure, and “O” is not limited to oxide and may include various types of organic or inorganic insulator materials.

Moreover, the conductivity type of a doped region or other component(s) may be defined as “p-type” or “n-type” according to the main carrier characteristics, but this is only for convenience of description, and the technical spirit of the present disclosure is not limited to what is illustrated. For example, the more general terms “first conductivity type” or “second conductivity type” will be used herein. For example, “first conductivity type” may refer to p-type, and “second conductivity type” may refer to n-type.

Furthermore, it should be understood that “high concentration” and “low concentration” referring to the doping concentration of an impurity region may mean a doping concentration of one component relative to another component.

Hereinafter, the term “first direction” should be understood to mean an x-axis direction or a y-axis direction in the illustrated drawings, and the term “second direction” should be understood to mean a direction orthogonal to the first direction in a horizontal plane. Hereinafter, for convenience, the first direction may refer to the x-axis direction in the drawings, and the second direction may refer to as the y-axis direction in the drawings, but the scope of the present disclosure is not limited thereto.

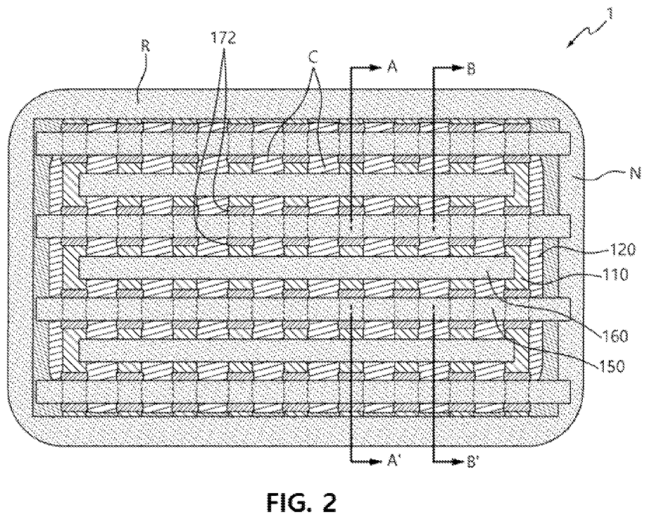

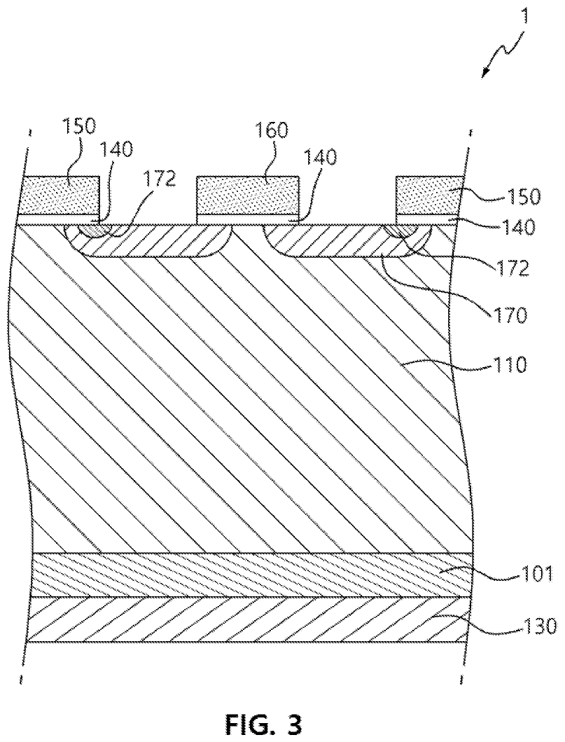

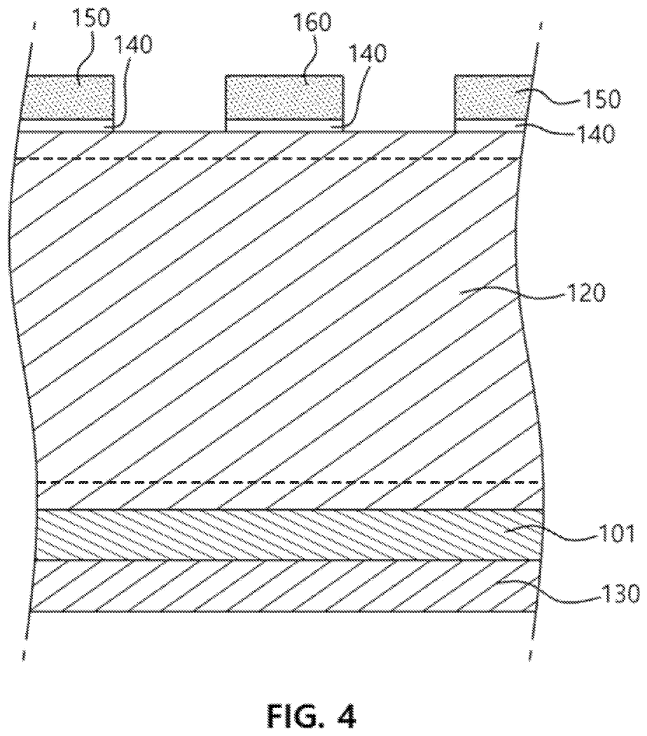

FIG. 2 is a plan view of a superjunction semiconductor device according to a first embodiment of the present disclosure, FIG. 3 is a cross-sectional view of the superjunction semiconductor device illustrated in FIG. 2 along the line A-A′, and FIG. 4 is a cross-sectional view of the superjunction semiconductor device illustrated in FIG. 2 along the line B-B′.

Hereinafter, a superjunction semiconductor device 1 according to an embodiment (first embodiment) of the present disclosure will be described in detail with reference to the accompanying drawings.

Referring to FIGS. 2 to 4, the present disclosure relates to the superjunction semiconductor device 1 and a method for manufacturing the same and, more particularly, to the superjunction semiconductor device 1 and a method for manufacturing the same seeking to improve a switching speed and thus improve switching characteristics by reducing a gate-drain parasitic capacitance (Cgd) and/or configuring a gate electrode as a floating dummy gate.

The superjunction semiconductor device 1 according to the first embodiment of the present disclosure includes a cell region C (which may be an active region of the device 1) and a ring region R (that may be a termination or peripheral region surrounding the cell region C). It should be noted that the structure of the superjunction semiconductor device 1 according to the first embodiment of the present disclosure is in the cell region C.

The structure of the device 1 will be described. The device 1 includes a substrate 101. The substrate 101 may include a silicon substrate or a germanium substrate, and may include a bulk (monolithic or single crystal) wafer and/or an epitaxial layer. The substrate 101 may comprise, for example, a lightly or heavily doped substrate having the second conductivity type.

An epitaxial layer 110, which may comprise an impurity-doped layer having the second conductivity type, is on the substrate 101 in the cell region C and the ring region R. In addition, a plurality of pillar regions 120 are in the epitaxial layer 110. The pillar regions 120 each comprise an impurity-doped region having the first conductivity type, and may extend to a predetermined depth in the epitaxial layer 110. The pillar regions 120 may be spaced apart from each other. For example, the plurality of pillar regions 120 may be spaced apart from each other in the first direction. That is, portions of the epitaxial layer 110 having the second conductivity type and the pillar regions 120 having the first conductivity type may alternate along the first direction. The pillar regions 120 may be in both the cell region C and the ring region R, but are not limited thereto.

A drain electrode 130 is on the substrate 101, on a major surface of the substrate 101 opposite from the epitaxial layer 120. In addition, a gate insulating film 140 is on the epitaxial layer 120. A plurality of gate electrodes 150 and a plurality of dummy gates 160 (to be described later) may be on the gate insulating film 140. The gate insulating film 140 comprises a silicon oxide (e.g., undoped or thermal silicon dioxide) layer, a high-k layer, or a combination thereof, and may be formed by, for example, atomic layer deposition (ALD), chemical vapor deposition (CVD), or physical vapor deposition (PVD).

The gate electrodes 150 may extend along the first direction and may be spaced apart from an adjacent or nearest gate electrode 150 in the second direction. Accordingly, the gate electrodes 150 may repeatedly cross the (alternating) epitaxial layer 110 portions and pillar regions 120. That is, in the device 1 according to the first embodiment of the present disclosure, unlike the second embodiment to be described later, the individual gate electrodes 150 and the dummy gates 160 extend (e.g., have a length) at an angle of about 90° to the horizontal extension direction (e.g., length, as opposed to height or depth) of the pillar regions 120.

As such, when the plurality of gate electrodes 150 extend in a direction substantially perpendicular to the alternating epitaxial layer 110 portions and pillar regions 120, it is relatively easy to adjust the separation distance in the second direction between adjacent or nearest gate electrodes 150 compared to the existing structure or the structure of a device 2 according to the second embodiment. That is, even when the distance between the gate electrodes 150 in the second direction is relatively long, the structure of the device 1 itself does not change compared to the structure of the existing device. Therefore, it is possible to easily adjust the channel density by adjusting the separation distance between the gate electrodes 150.

As previously described, the dummy gate 160 also extends in the first direction and may be spaced apart from the adjacent gate electrode 150 and/or the nearest dummy gate 160 in the second direction. The dummy gate 160 is electrically and physically separate from a gate node N (in the ring or peripheral region R) to maintain a floating state. In addition, the gate electrodes 150 and/or other dummy gates 160 may be adjacent to and/or spaced apart from a specific one of the dummy gates 160 in the second direction. That is, the plurality of dummy gates 160 may have sides along the second direction, or may alternate with the gate electrodes 150. The total area ratio between the dummy gate and the gate electrode 150 is variable and there is no special limitation thereto.

A plurality of body regions 170, each of which is an impurity-doped region having the first conductivity type, are in the epitaxial layer 110 and optionally under the gate electrodes 150 and the dummy gates 160. The body regions 170 may contact the pillar regions 120 in a lateral direction. The body regions 170 may alternate with the pillar regions 120 in the first direction. A source region 172 that is a heavily doped region having a second conductivity type is in each of the body regions 170.

The source region 172 may partially overlap the corresponding gate electrode 150. In addition, one or two source regions 172 may be in each individual body region 170. For example, when two source regions 172 are in an individual body region 170, two current paths may be formed. A side or portion of the body region containing a source region 172 is referred to as a first body portion, and a side or portion of the body region not containing a source region 172 is referred to as a second body portion.

In general high-voltage and high-current power systems, when a short-circuit occurs, high voltage and high current may simultaneously pass through the device, resulting in high power consumption. If this phenomenon continues, the junction temperature rises, which may eventually destroy the device. When two source regions 172 are in the body region 170, a current value (Isc) during a short-circuit may be relatively large. To solve this problem, only one source region 172 may be in the body region 170 in order to reduce the area of the source region 172 and/or the number of channels in the device.

Hereinafter, the structure of a conventional superjunction semiconductor device 9 and its problems, as well as the structure of the superjunction semiconductor device 1 according to the embodiment of the present disclosure for solving those problems will be described with reference to the accompanying drawings.

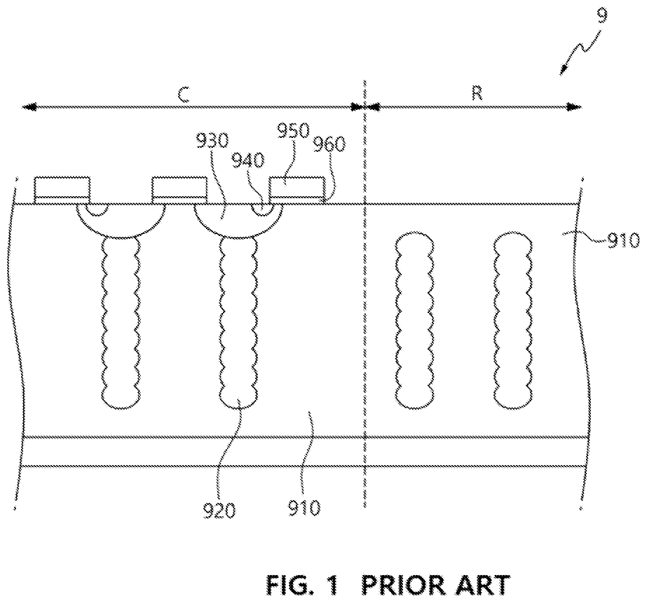

Referring to FIG. 1, when one source region 940 is in a single body region 930 to lower the short-circuit current value (Isc) in the conventional superjunction semiconductor device 9, the side of body region 930 without the source region 940 does not function as a channel, but the gate 950 is still thereover, and thus a gate-drain parasitic capacitance (Cgd) is maintained. The gate-drain parasitic capacitance (Cgd) has a linear relationship with the area between the epitaxial layer 910 and the gate oxide film 960 between the epitaxial layer 910 and the gate 950. Moreover, since a current path cannot form, the resistance value becomes relatively large, which causes a decrease in the switching speed of the device 9 and a deterioration in its switching characteristics.

In order to solve such problems, referring to FIGS. 2 to 4, in the superjunction semiconductor device 1 according to one embodiment of the present disclosure, the gate on the side of the body region 170 without a source region 172 is a dummy gate 160. Since the dummy gate 160 is floating (e.g., neither physically nor electrically connected to the gate node N), it is possible to reduce the value of the gate-drain parasitic capacitance (Cgd) to reduce or prevent deterioration of switching characteristics as much as possible. That is, in the superjunction semiconductor device 1 according to the present disclosure, the dummy gate 160 is over a pair of adjacent second body portions. In addition, in order to lower the gate-drain parasitic capacitance (Cgd), the gate electrodes 150 and the dummy gates 160 may be omitted over the second body portions. However, in this case, the step coverage in subsequent processing (i.e., after forming the gates) may deteriorate because the gate electrodes 150 may be at unequal intervals or may be spaced farther apart along the second direction.

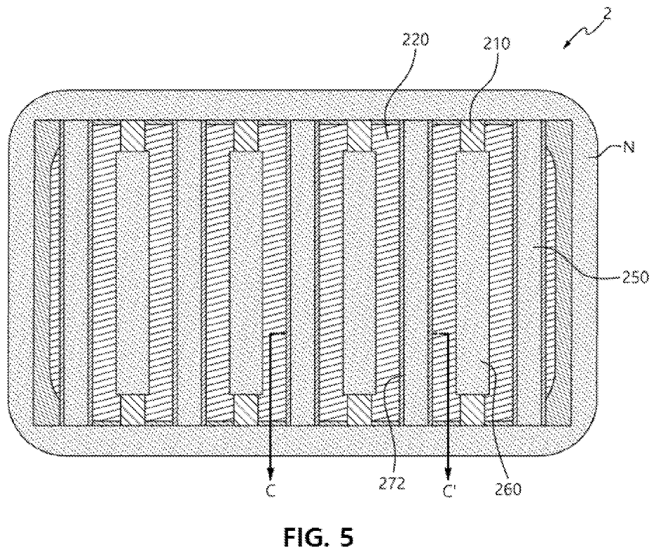

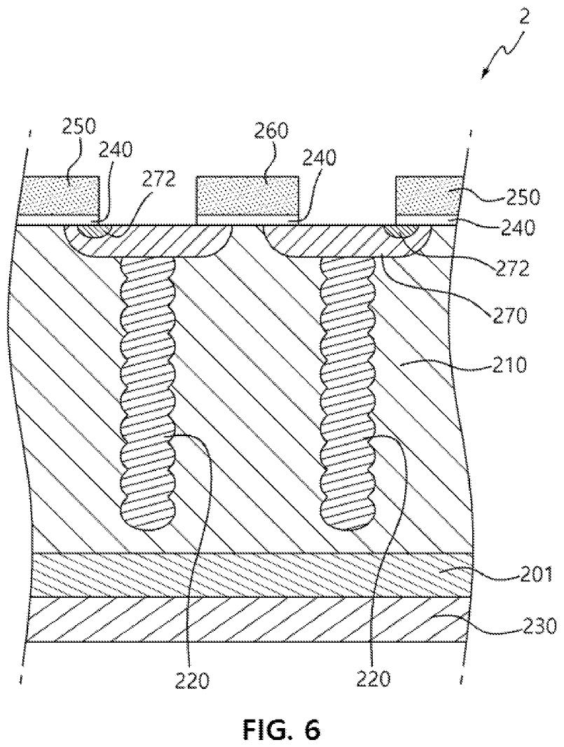

FIG. 5 is a plan view of a superjunction semiconductor device according to a second embodiment of the present disclosure, and FIG. 6 is a cross-sectional view of the superjunction semiconductor device illustrated in FIG. 5 along the line C-C′.

Hereinafter, a superjunction semiconductor device 2 according to another embodiment (second embodiment) of the present disclosure will be described in detail with reference to the accompanying drawings. In describing the second embodiment, a detailed description of the content similar to or overlapping with the first embodiment will be omitted.

Referring to FIGS. 5 and 6, the superjunction semiconductor device 2 may be configured such that an epitaxial layer 210 is on a substrate 201, and a plurality of pillar regions 220 in the epitaxial layer 210 may have a predetermined depth and be spaced apart from each other along the first direction. Accordingly, portions of the epitaxial layer 210 and the pillar regions 220 may alternate along the first direction.

A drain electrode 230 is on the bottom surface of the substrate 201, opposite from the epitaxial layer 210. In addition, a gate insulating film 240 is on the epitaxial layer 210, and a plurality of gate electrodes 250 are on the gate insulating film 240. Both the gate insulating film 240 and the gate electrodes 250 may extend in the second direction and may be spaced apart from adjacent gate insulating films 240 and adjacent gate electrodes 250 in the first direction. In addition, at least one dummy gate 260 may be between any pair of adjacent or nearest gate electrodes 250. The gate insulating film 240 may also be between each dummy gate 260 and the epitaxial layer 210. As described above, in the second embodiment, different from the first embodiment, the gate insulating film 240, the gate electrode 250, and the dummy gate 260 all extend in the second direction, so that they do not cross the alternating epitaxial layer 210 portions and pillar regions 220, but rather, extend in the same direction as the pillar regions 220. The dummy gate 260 is floating (e.g., neither physically nor electrically connected to the gate node N), which is the same as in the first embodiment.

Furthermore, a plurality of body regions 270 (i.e., impurity-doped regions having the first conductivity type) are in the epitaxial layer 210 and optionally under the gate electrodes 250 and the dummy gate(s) 260 (or sidewall[s] thereof). The body regions 270 also extend in the second direction and are spaced apart from adjacent body region(s) 270 in the first direction. At least one source region 272 may be in each of the body regions 270. The source region 272 is not adjacent to or under the dummy gate 260 or a sidewall thereof, and is preferably closer or adjacent to and/or under a sidewall of the nearest gate electrode 250. The source region 272 may also extend in the second direction and be spaced apart from the nearest source region(s) 272 in the first direction.

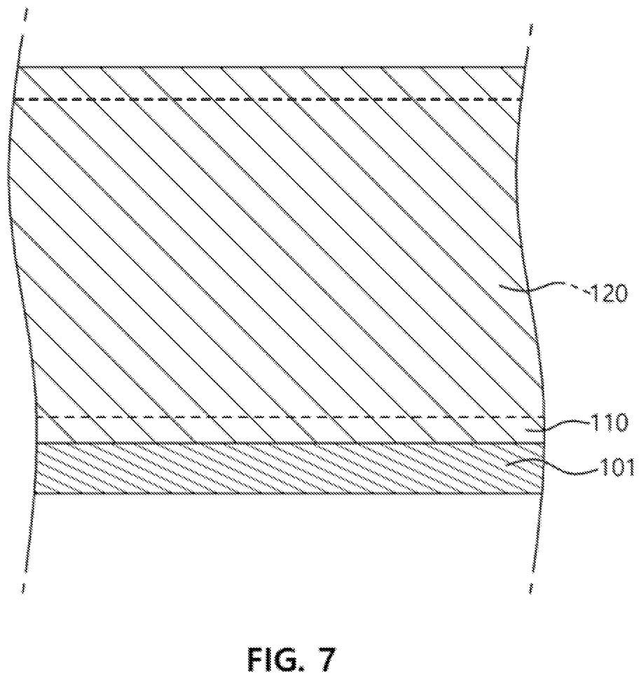

FIGS. 7 to 11 are reference views illustrating structures made during a method of manufacturing the superjunction semiconductor device according to the first embodiment of the present disclosure.

Hereinafter, a method for manufacturing a superjunction semiconductor device according to an embodiment (first embodiment) of the present disclosure will be described in detail with reference to the accompanying drawings.

Referring to FIG. 7, first, the epitaxial layer 110 having the second conductivity type and the pillar regions 120 having the first conductivity type are formed on the substrate 101. To be specific, for example, the epitaxial layer 110 (or a portion thereof) is deposited on the substrate 101 by epitaxial deposition or growth, and an impurity region having the first conductivity type is implanted in the epitaxial layer (or a portion thereof) in a predetermined region by conventional photolithographic patterning and ion implantation (e.g., using a photoresist pattern as an ion implantation mask). If the epitaxial layer 110 is formed by successive cycles of deposition of a portion of the epitaxial layer 110 and implantation of first conductivity type impurities, one or more initial portions and one or more final portions of the epitaxial layer 110 may be formed without subsequent implantation of the first conductivity type impurities. The pillar regions 120 are formed after complete deposition of the epitaxial layer 110 and implantation of the first conductivity type impurities into the predetermined regions of the epitaxial layer 110 by thermal diffusion and annealing (e.g., heat treatment).

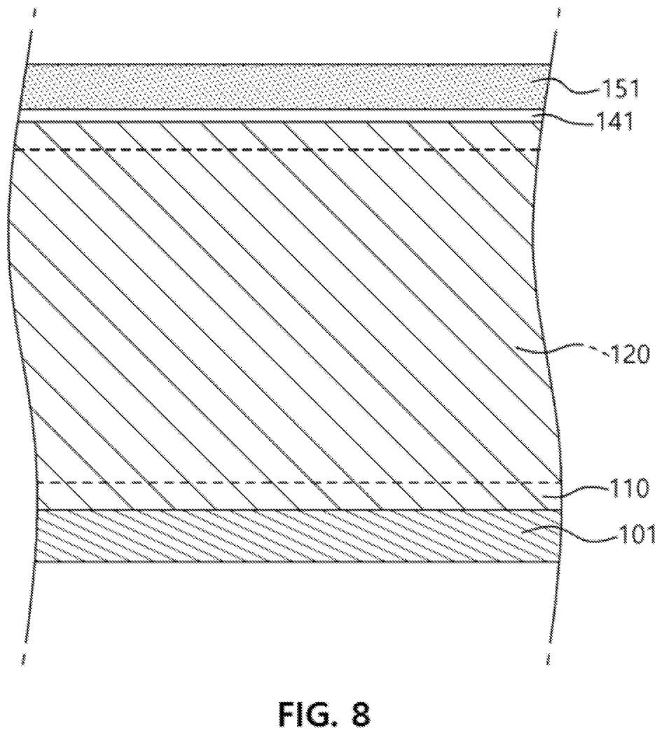

Thereafter, referring to FIG. 8, an insulating film 141 is deposited on the epitaxial layer 110, and a gate film 151 is formed on the insulating film 141. The insulating film 141 may comprise, for example, a silicon dioxide film formed by wet or dry thermal oxidation, or a high-k dielectric film, but is not limited thereto. The gate film 151 may comprise, for example, a conductive polysilicon film, but is not limited thereto, and may be deposited by convention blanket deposition (e g , ALD, CVD, PVD, etc.).

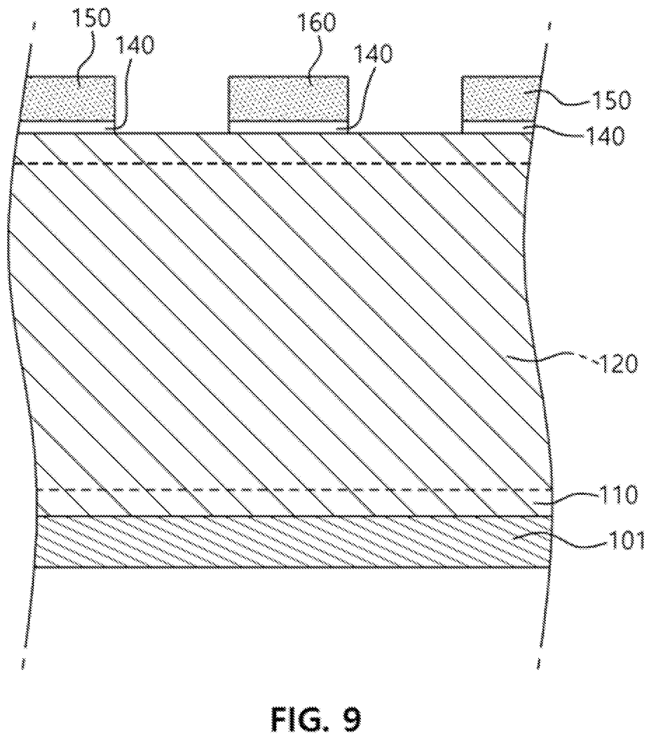

Thereafter, referring to FIG. 9, the gate film 151 and the insulating film 141 are sequentially etched (following conventional photolithographic patterning using a photoresist pattern as an etching mask) to form the gate electrode 150, the dummy gate 160, and the gate insulating film 140. Components such as the gate electrode 150 are patterned to extend along the first direction. That is, the components may be substantially perpendicular to the pillar regions 120.

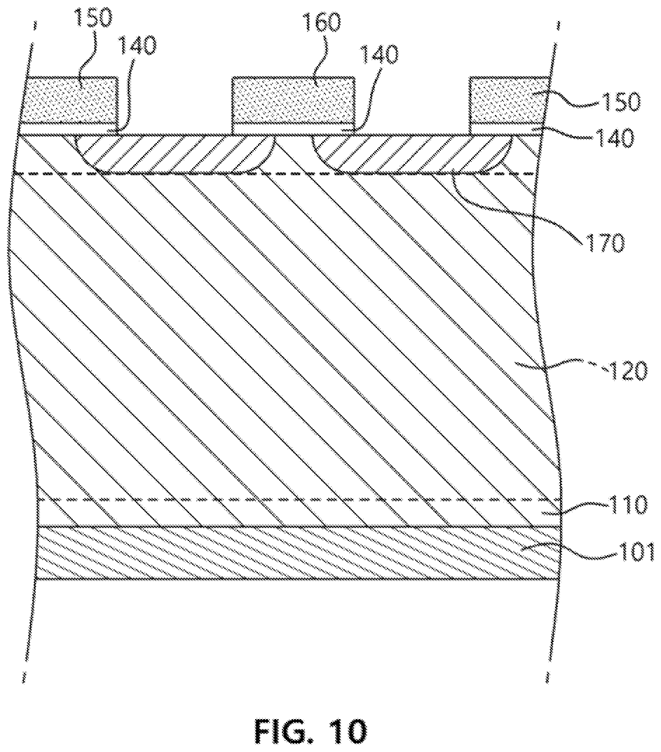

Thereafter, referring to FIG. 10, the body regions 170 are formed in the epitaxial layer 110. To be specific, the body regions 170 may be formed by implanting a first conductivity type impurity into the exposed regions of the epitaxial layer by using the gate electrodes 150 and the dummy gates 160 as a mask pattern. The body regions 170 may include a first body portion and/or a second body portion, depending on the formation of the source region 172 to be described later. In addition, the body regions 170 may be connected to or in contact with the pillar regions 120 along the lateral direction.

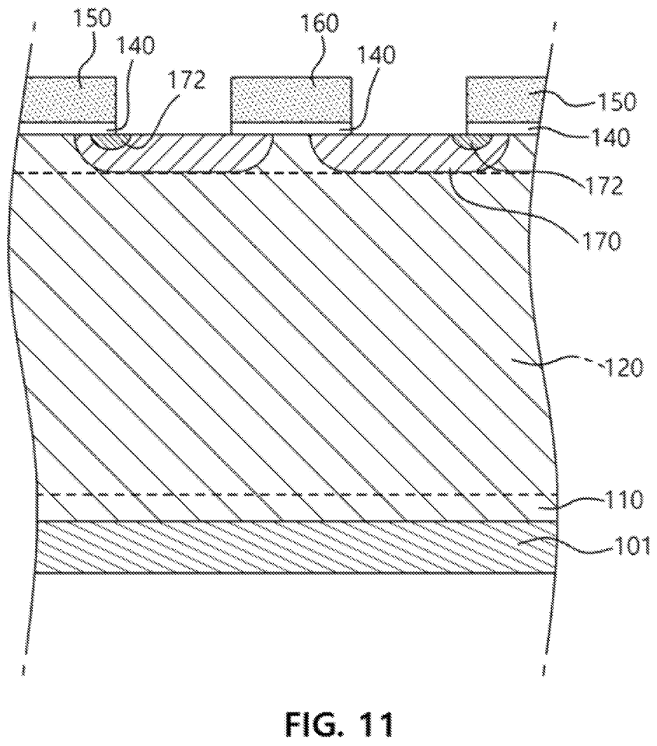

Finally, referring to FIG. 11, the source regions 172 are formed in the body regions 170. It is preferable that the source regions 172 are not formed adjacent to or under the dummy gate 160, but rather, are formed adjacent to and/or under a sidewall of the gate electrodes 150. The source regions 172 may be formed by conventional photolithographic patterning and ion implantation, using a photoresist pattern as an ion implantation mask, or by angled ion implantation, using the gate electrodes 150 and the dummy gates 160 as a mask. Such ion implantation may be performed at a relatively low energy, but using a relatively high dose of first conductivity type impurities.

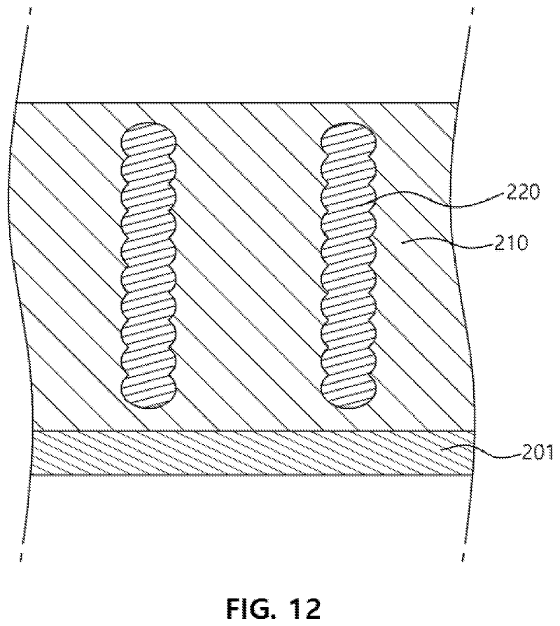

FIGS. 12 to 16 are cross-sectional views illustrating structures made during a method of manufacturing the superjunction semiconductor device according to a second embodiment of the present disclosure.

Hereinafter, a method of manufacturing a superjunction semiconductor device according to another embodiment (second embodiment) of the present disclosure will be described in detail with reference to the accompanying drawings.

First, referring to FIG. 12, a second conductivity type epitaxial layer 210 and a plurality of first conductivity type pillar regions 220 are formed on the substrate 201. The epitaxial layer 220 may be formed by, for example, epitaxial growth. A process for forming the epitaxial layer 210 and the pillar regions 220 will be described by way of example. After forming an implant layer including an impurity region having the first conductivity type in a predetermined region of each of a plurality of successively-grown epitaxial layers having the second conductivity type, the pillar regions 220 may be formed by diffusion and annealing (e.g., heat treatment).

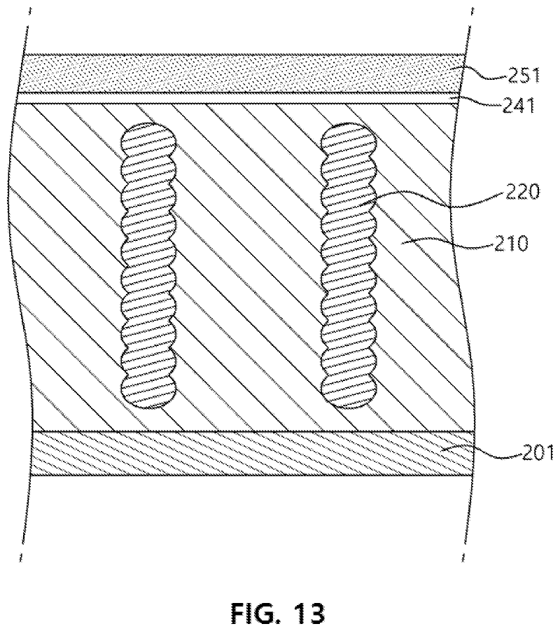

Thereafter, referring to FIG. 13, an insulating film 241 is formed on the epitaxial layer 210, and a gate film 251 is formed on the insulating film 241 in the same manner as the insulating film 141 and the gate film 151 in FIG. 8. The gate film 251 may comprise, for example, a conductive polysilicon film.

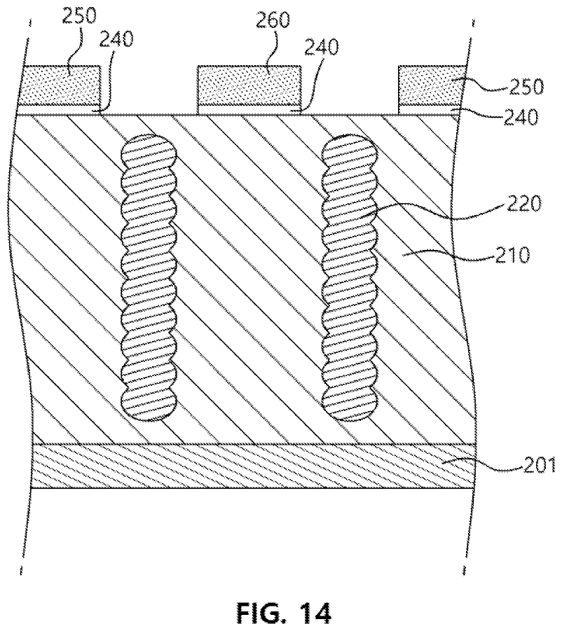

Thereafter, referring to FIG. 14, after a mask pattern (not shown) is formed on the gate film 251 (e.g., by conventional photolithographic patterning), the gate film 251 and the insulating film 241 are sequentially etched using the mask pattern. Accordingly, the gate insulating film 240 may be formed, and the gate electrodes 250 and/or the dummy gates 260 may be formed thereon. As previously described, the dummy gates 260 may be patterned so that the dummy gates 260 are not connected to the gate node N to maintain a floating state. Unlike the structure of the superjunction semiconductor device 1 according to the first embodiment, the gate electrode 250 and the dummy gate 260 may have an axis along their longest dimension parallel to the axis along the longest dimension of the pillar regions 220 and/or may not cross the alternating epitaxial layer 210 portions and pillar regions 220.

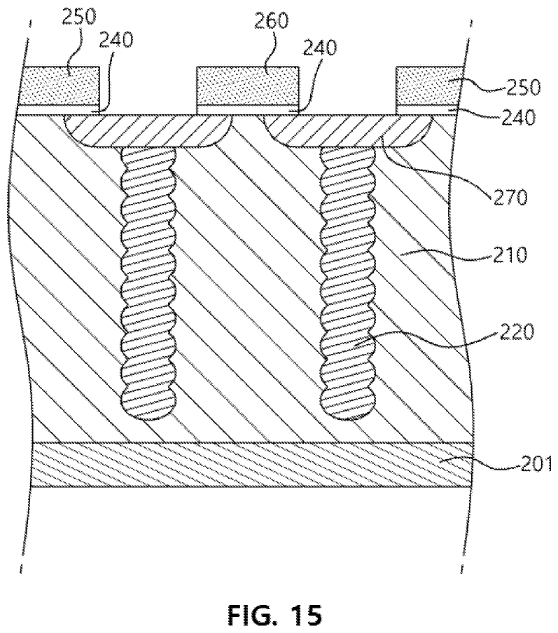

Thereafter, referring to FIG. 15, the body regions 270 are formed in the epitaxial layer 210 in the same manner as the body regions 170 in FIG. 10. To be specific, the body regions 270 may be formed by implanting a first conductivity type impurity into the epitaxial layer 210 above each pillar region 220 using the gate electrodes 250 and the dummy gates 260 as a mask pattern.

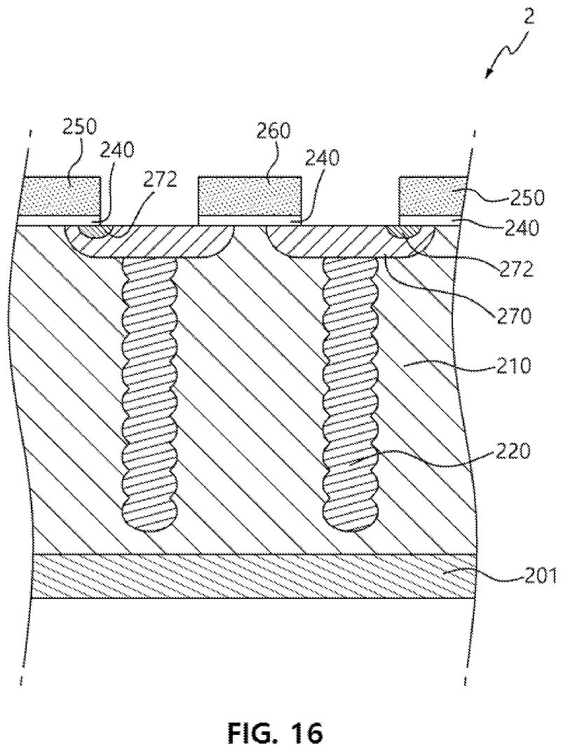

Thereafter, referring to FIG. 16, a source region 272 is formed in each body region 270 in the same manner as the source regions 172 in FIG. 11. It is preferable that the source regions 272 are not formed adjacent to or under the dummy gate 260, but rather, are formed adjacent to and/or under a sidewall of the gate electrodes 250. One source region 272 may be formed in each body region 270, or a pair of the source regions 272 may be formed in each body region 270, and there is no special limitation thereto.

The above detailed description is illustrative of the present disclosure. In addition, the above description shows and describes various embodiments of the present disclosure, and the present disclosure can be used in various other combinations, modifications, and environments. That is, changes or modifications are possible within the scope of the concept of the disclosure herein, the scope equivalent to the written disclosure, and/or within the scope of skill or knowledge in the art. The above-described embodiments describe various ways for implementing the technical idea(s) of the present disclosure, and various changes for specific applications or fields of use of the present disclosure are possible. Accordingly, the detailed description of the present disclosure is not intended to limit the present disclosure to the disclosed embodiments.

What is claimed is:

1. A superjunction semiconductor device, comprising:
a substrate;
a drain electrode on the substrate;
an epitaxial layer on the substrate;
a plurality of pillar regions spaced apart from each other in the epitaxial layer;
a gate electrode on the epitaxial layer;
a dummy gate on the epitaxial layer;
a body region in the epitaxial layer; and
a source region in the body region,
wherein the source region is adjacent to or under the gate electrode or a sidewall thereof, but is not adjacent to or under the dummy gate or a sidewall thereof.

2. The superjunction semiconductor device of claim 1, comprising a plurality of gate electrodes, wherein the dummy gate extends in a same direction as the gate electrode, and is between adjacent ones of the gate electrodes.

3. The superjunction semiconductor device of claim 1, comprising a plurality of gate electrodes and a plurality of dummy gates, wherein the dummy gates extend in a same direction as the gate electrodes, and alternate with the gate electrodes.

4. The superjunction semiconductor device of claim 1, further comprising a gate node, wherein the dummy gate is physically separate from the gate node.

5. The superjunction semiconductor device of claim 1, wherein the pillar regions are spaced apart from each other in a first direction, and
the gate electrode and the dummy gate extend in the first direction, and are spaced apart from an adjacent gate electrode and/or an adjacent dummy gate in a second direction.

6. The superjunction semiconductor device of claim 1, wherein the plurality of pillar regions alternate with portions of the epitaxial layer at a predetermined height.

7. A superjunction semiconductor device, comprising:
a substrate;
a drain electrode on the substrate;
an epitaxial layer having a second conductivity type on the substrate;
a plurality of pillar regions spaced apart from each other in a first direction in the epitaxial layer, and alternating with portions of the epitaxial layer along the first direction at a predetermined height or depth;
a plurality of gate electrodes extending in a second direction on the epitaxial layer, and spaced apart from adjacent ones of the gate electrodes in the first direction;
a plurality of dummy gates extending in the second direction on the epitaxial layer, and spaced apart from the adjacent ones of the gate electrodes and/or adjacent ones of the dummy gates in the first direction;
a body region having a first conductivity type in the epitaxial layer and on one of the pillar regions; and
a source region having the second conductivity type in the body region.

8. The superjunction semiconductor device of claim 7, wherein the superjunction semiconductor device comprises a plurality of body regions and a plurality of source regions, and there is only one source region in each of the body regions.

9. The superjunction semiconductor device of claim 7, wherein each of the gate electrodes at least partially overlaps a corresponding one of the source regions in a vertical direction, and
each of the dummy gates has a shorter length in the second direction than the gate electrodes.

10. The superjunction semiconductor device of claim 9, wherein each of the dummy gates does not overlap any of the source regions in the vertical direction.

11. The superjunction semiconductor device of claim 10, wherein the dummy gates correspond one-to-one with the gate electrodes.

12. A method for manufacturing a superjunction semiconductor device, the method comprising:
forming a plurality of epitaxial layers on a substrate;
forming an implant layer including an impurity region having a first conductivity type in one or more of the epitaxial layers;
forming a pillar region in the one or more epitaxial layers by diffusion;
forming a gate electrode on or over the epitaxial layers; and
forming a dummy gate on or over the epitaxial layers,
wherein the gate electrode and the dummy gate extend in a direction substantially orthogonal to the pillar region.

13. The method for manufacturing a superjunction semiconductor device of claim 12, further comprising:
forming a body region in the epitaxial layers connected to the pillar region and overlapping the gate electrode and/or the dummy gate; and
forming a source region in the body region so that the source region does not overlap the dummy gate.

14. The method for manufacturing a superjunction semiconductor device of claim 12, wherein the source region overlaps a sidewall of the gate electrode in a vertical direction.

15. The method for manufacturing a superjunction semiconductor device of claim 12, wherein the dummy gate has a substantially same cross-sectional shape as the gate electrode.

16. The method for manufacturing a superjunction semiconductor device of claim 12, further comprising forming a gate node on or over the substrate and/or the epitaxial layers, and the dummy gate is formed so that it is not connected to the gate node.

17. A method for manufacturing a superjunction semiconductor device, the method comprising:
forming an epitaxial layer on a substrate;
forming a plurality of pillar regions spaced apart from each other in a first direction in the epitaxial layer;
forming, in the epitaxial layer, a body region having a first body portion and a second body portion on one of the pillar regions;
forming a source region in the first body region;
forming a gate electrode on the epitaxial layer adjacent to and/or over the first body portion; and
forming a dummy gate on the epitaxial layer adjacent to and/or over the second body portion.

18. The method for manufacturing a superjunction semiconductor device of claim 17, wherein the source region is not formed in the second body portion.

19. The method for manufacturing a superjunction semiconductor device of claim 18, wherein the dummy gate is floating.

20. The method for manufacturing a superjunction semiconductor device of claim 19, wherein the source region extends in a second direction with the gate electrode, the dummy gate, and the pillar regions.
